(19) United States
(12) Patent Application Publication
(10) Pub. No.: US 2021/0079519 A1
(43) Pub. Date: Mar. 18, 2021

(54) METHOD AND APPARATUS FOR FORMING A PATTERNED LAYER OF MATERIAL

(71) Applicant: ASML NETHERLANDS B.V., Veldhoven (NL)

(72) Inventors: Pieter Willem Herman DE JAGER, Middelbeers (NL); Sander Frederik WUISTER, Eindhoven (NL); Marie-Claire VAN LARE, Utrecht (NL); Ruben Cornelis MAAS, Utrecht (NL); Alexey Olegovich POLYAKOV, Veldhoven (NL); Tamara DRUZHININA, Eindhoven (NL); Victoria VORONINA, Veldhoven (NL); Evgenia KURGANOVA, Nijmegen (NL); Jim Vincent OVERKAMP, Eindhoven (NL); Bernardo KASTRUP, Veldhoven (NL); Maarten VAN KAMPEN, Eindhoven (NL); Alexandr DOLGOV, Waalre (NL)

(73) Assignee: ASML NETHERLANDS B.V., Veldhoven (NL)

(21) Appl. No.: 16/971,012

(22) PCT Filed: Feb. 21, 2019
(86) PCT No.: PCT/EP2019/054313

§ 371 Date: Aug. 19, 2020

(30) Foreign Application Priority Data
Feb. 3, 2018 (EP) 18159656.0
Oct. 5, 2018 (EP) 18198942.7
Nov. 5, 2018 (EP) 18204446.1

(51) Int. Cl. C23C 16/04; C23C 16/455; C23C 16/48

(52) U.S. Cl. CPC C23C 16/047; C23C 16/483; C23C 16/45544

(57) ABSTRACT

Methods and apparatuses for forming a patterned layer of material are disclosed. In one arrangement, a selected portion of a surface of a substrate is irradiated with electromagnetic radiation having a wavelength of less than 100 nm during a deposition process. Furthermore, an electric field controller is configured to apply an electric field that is oriented so as to force secondary electrons away from the substrate. The irradiation locally drives the deposition process in the selected portion and thereby causes the deposition process to, for example, form a layer of material in a pattern defined by the selected portion.

### CROSS-REFERENCE TO RELATED APPLICATIONS

This application claims priority of EP application 18159656.0 which was filed on Mar. 2, 2018 and EP application 18198942.7 which was filed on Oct. 5, 2018 and EP application 18204446.1 which was filed on Nov. 5, 2018 which are incorporated herein in its entirety by reference.

### FIELD

The present invention relates to methods and apparatus for forming a patterned layer of material.

### BACKGROUND

As semiconductor manufacturing processes continue to advance, the dimensions of circuit elements have continually been reduced while the amount of functional elements, such as transistors, per device has been steadily increasing over decades, following a trend commonly referred to as ‘Moore’ s law′. To keep up with Moore's law the semiconductor industry is chasing technologies that enable creation of increasingly smaller features.

Many semiconductor manufacturing processes rely on lithography. Exposure of a substrate during lithography is performed field by field, whereas most or all other steps (e.g. etching, depositing, chemical mechanical planarization (CMP), implanting) are performed for the whole substrate simultaneously. As lithography processing moves to smaller features, requirements for uniformity across the substrate increase, which means that full substrate processing is becoming more challenging. Critical dimension uniformity may be limited by chemical noise in photo-resist.

The tunnelling FET is a promising candidate for incorporation into future transistor layouts because of its short decay time and zero dark-current (and therefore low power consumption). Fabrication of tunnelling FETs is challenging because of the need to form patterned stacks of atomic monolayers, such as MoS₂. Lithography can be used to perform the patterning but it has been found that processes for etching or stripping photo-resist can introduce defects into the atomic monolayers, thereby affecting yield.

### SUMMARY

It is an object of the invention to provide alternative or improved methods and apparatus for forming patterned layers.

According to one aspect, there is provided a method of forming a patterned layer of material, comprising: irradiating a selected portion of a surface of a substrate with electromagnetic radiation having a wavelength of less than 100 nm during a deposition process, the irradiation being such as to locally drive the deposition process in the selected region and thereby cause the deposition process to form a layer of material in a pattern defined by the selected portion.

Thus, a method is provided in which a radiation pattern defines where a deposition process (which may comprise e.g. an atomic layer deposition process or a chemical vapour deposition process) occurs, thereby allowing a patterned layer of material to be formed without the need for a resist. Use of EUV radiation (radiation having a wavelength less than 100 nm) has been found to be effective and practical, thereby allowing high resolution features to be formed using the disclosed technique. Potentially damaging processing steps associated with removing resist can be avoided. In the context of semiconductor device manufacturing, it is expected that errors associated with chemical noise can be reduced because precursor materials used in deposition are small molecules in comparison with typical resist materials. The contribution from chemical noise to local critical dimension non-uniformity is expected to be smaller than for chemically amplified resists and non-chemically amplified resists where the building block is either a polymer or a metal oxide nanoparticle. Improving local critical dimension uniformity can contribute to improve edge placement accuracy of device features.

Irradiating the substrate during the deposition process (e.g. atomic layer deposition process) not only allows patterns to be defined directly but can also speed up the deposition process (e.g. atomic layer deposition process) relative to configurations which do not use irradiation, thereby providing good throughput.

Because the driving of the deposition process (e.g. atomic layer deposition process) involves chemical reactions occurring intrinsically at the surface being processed, the accuracy of resulting patterns will be relatively insensitive to variations in the stack below the surface.

A single integrated process achieves what would need several distinct processes in an alternative resist-based semiconductor manufacturing process (e.g. exposure, development, deposition, etc.). This may provide increased scope for process optimization.

In an embodiment, the driving of the deposition process (e.g. atomic layer deposition process) in the selected portion comprises driving a chemical reaction involving a precursor material, wherein the chemical reaction comprises a photochemical reaction driven by the irradiation, and the photochemical reaction is a multi-photon photochemical reaction involving absorption of two or more photons by each of at least one species involved in the photochemical reaction. Configuring the atomic layer deposition so that the irradiation drives multi-photon photochemical reactions allows particularly high spatial contrast to be achieved.

In an embodiment, the driving of the chemical reaction comprises generating a reactive species by the radiation locally interacting with a gas above the selected region. Using the radiation to locally generate reactive species allows spatially controlled deposition or modification of a wide range of materials.

According to an aspect, there is provided a method of forming a patterned layer of material, comprising: irradiating a selected portion of a surface of a substrate with electromagnetic radiation during an atomic layer deposition process, the irradiation being such as to locally drive the atomic layer deposition process in the selected region and thereby cause the atomic layer deposition process to form a layer of material in a pattern defined by the selected portion, wherein: the atomic layer deposition process comprises two steps and the irradiation of the selected portion is performed during at least one of the two steps and while the selected portion of the substrate is in contact with a liquid.

Thus, a method is provided in which a radiation pattern applied during an immersion process (where the selected portion is covered with liquid) can define where an atomic layer deposition process occurs, thereby allowing a patterned layer of material to be formed without the need for a resist in an expanded range of atomic layer deposition procedures (in comparison to the case where the radiation pattern is applied purely through a gaseous environment). A flow of the immersion liquid can also conveniently carry away by-products produced by the irradiation.

According to an aspect, there is provided an apparatus for forming a patterned layer of material, comprising: an irradiation system configured to irradiate a selected portion of a surface of a substrate with electromagnetic radiation having a wavelength of less than 100 nm during a deposition process; and an environment control system configured to allow the composition of the environment above the substrate to be controlled in such a way as to allow the deposition process to proceed.

According to an aspect, there is provided an apparatus for forming a patterned layer of material, comprising: an irradiation system configured to irradiate a selected portion of a surface of a substrate with electromagnetic radiation during a deposition process; and an environment control system configured to allow the composition of the environment above the substrate to be controlled in such a way as to allow the deposition process to proceed, wherein the environment control system is configured to allow a liquid to be maintained in contact with the selected portion during irradiation of the selected portion in at least one step of the deposition process.

In an embodiment, the irradiation system comprises a lithographic apparatus configured to provide the irradiation of the selected portion by projecting a patterned radiation beam from a patterning device onto the substrate.

Thus, capabilities of lithography apparatus developed to achieve high precision exposure of resist can be exploited to allow accurate formation of patterns in a deposition process (e.g. an atomic layer deposition process) without using resist. High accuracy can be achieved using fewer processing steps and/or without losses in yield associated with having to remove resist.

According to an aspect, there is provided a method of forming a patterned layer of material, comprising: providing a stack comprising a substrate and a monolayer of material; and processing the stack to remove material in one or more selected regions of the monolayer of material by selectively irradiating the material in the one or more selected regions, thereby applying a pattern to the monolayer of material or modifying a pattern in the monolayer of material. Using selective irradiation of the material in the monolayer of material to remove the material in the one or more selected regions allows the pattern to be formed or modified in a single step, thereby facilitating high throughput.

In an embodiment, the removal of material occurs by laser ablation. The inventors have found that laser ablation provides high efficiency, accuracy and reliability, even when applied to monolayers of materials.

According to an aspect, there is provided a method of forming a patterned layer of material, comprising: providing a stack comprising a substrate and a layer of material; and irradiating one or more selected regions of the layer of material with electromagnetic radiation having a wavelength of less than 100 nm to apply a pattern to the layer of material or modify a pattern in the layer of material, wherein: the irradiation causes removal of material during the irradiation by generating a plasma in the region above the substrate; and the radiation interacts with the substrate to locally suppress the removal of material in the one or more selected regions relative to other regions in order to apply the pattern or modify the pattern. This approach allows high precision and flexible control of regions to be removed (e.g. etched) during a removal process, without requiring any lithographic patterning steps such as exposure and development to be performed separately from the removal process in order to define the regions to be removed.

According on an aspect, there is provided an apparatus for forming a patterned layer of material, comprising: an irradiation system configured to irradiate one or more selected regions of a layer of material on a substrate with electromagnetic radiation having a wavelength of less than 100 nm; and an environment control system configured to allow the composition of the environment above the substrate to be controlled during the irradiation, wherein: the environment control system is configured to control the environment to provide a plasma-promoting material in the environment; the plasma-promoting material is such as to cause a plasma to be generated by the electromagnetic radiation as the electromagnetic radiation passes through the controlled environment; the plasma is such as to cause removal of material in the layer of material during the irradiation; and the radiation interacts with the substrate to locally suppress the removal of material in the one or more selected regions relative to other regions, thereby applying a pattern to the layer of material or modifying a pattern in the layer of material.

### BRIEF DESCRIPTION OF THE DRAWINGS

Embodiments of the invention will now be described, by way of example only, with reference to the accompanying schematic drawings, in which:

FIG. 1 depicts a first example of a lithographic system comprising a lithographic apparatus and a radiation source;

FIG. 2 depicts a second example of a lithographic system comprising a lithographic apparatus and a radiation source;

FIG. 3 is a schematic side view of a tunnelling FET;

FIG. 4 schematically depicts irradiation of a selected region on a substrate during a first step of an atomic layer deposition process;

FIG. 5 schematically depicts a step in the atomic layer deposition process subsequent to the step depicted in FIG. 4;

FIG. 6 schematically depicts a lithographic apparatus providing radiation to an environment control system according to an embodiment;

FIG. 7 schematically depicts irradiation of a selected portion of a substrate to locally drive a pyrolytic chemical reaction forming part of an atomic layer deposition process;

FIG. 8 schematically depicts a step in the atomic layer deposition process subsequent to the step depicted in FIG. 7;

FIG. 9 schematically depicts irradiation of a selected portion of a substrate to locally generate a reactive species participating in an atomic layer deposition process;

FIG. 10 is a schematic side sectional view depicting selective irradiation of material in one or more selected regions of a monolayer of the material;

FIG. 11 is a schematic side sectional view depicting the stack of FIG. 10 after the selective irradiation has caused removal of material in the selected regions;

FIG. 12 is a graph showing variation in depth of cutting during a laser ablation process as a function of the number of applied pulses;

FIG. 13 schematically depicts a lithographic apparatus providing radiation to an environment control system;

FIG. 14 is a schematic side view of a substrate being irradiated in a method of forming a patterned layer of material;

FIG. 15 is a graph demonstrating how EUV radiation can provide local protection against a plasma etching process;

FIG. 16 is a graph showing how a strength of the local protection shown in FIG. 15 varies as a function of intensity of the EUV radiation; and

FIG. 17 schematically depicts a variation on the method depicted in FIG. 14 in which an electric field is applied to enhance yield and pattern definition.

### DETAILED DESCRIPTION

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus which uses extreme ultraviolet (EUV) radiation, having a wavelength of less than 100 nm, optionally in the range of 5-100 nm, optionally within a range of 4 nm to 20 nm, for example 6.7 nm or 13.5 nm, may be used to form smaller features on a substrate than a lithographic apparatus which uses, for example, radiation with a wavelength of 193 nm.

In the present document, the terms “radiation” and “beam” are used to encompass all types of electromagnetic radiation unless stated otherwise, including ultraviolet radiation (e.g. with a wavelength of 365, 248, 193, 157 or 126 nm) and EUV (extreme ultra-violet radiation, e.g. having a wavelength in the range of about 5-100 nm).

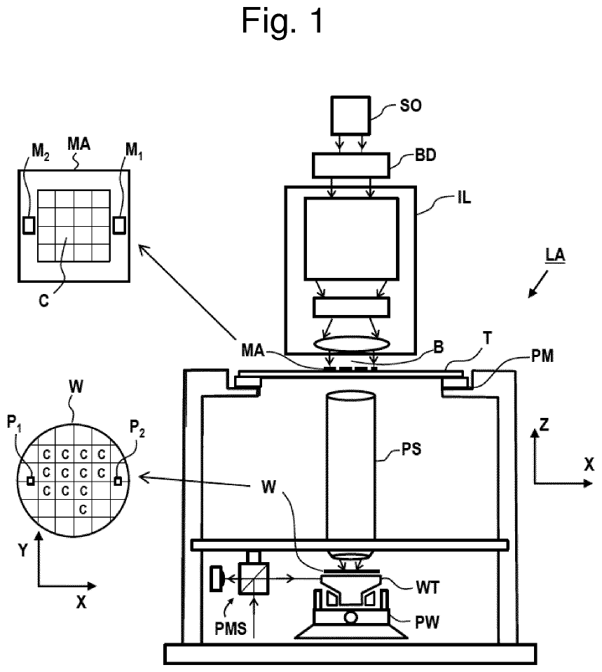

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

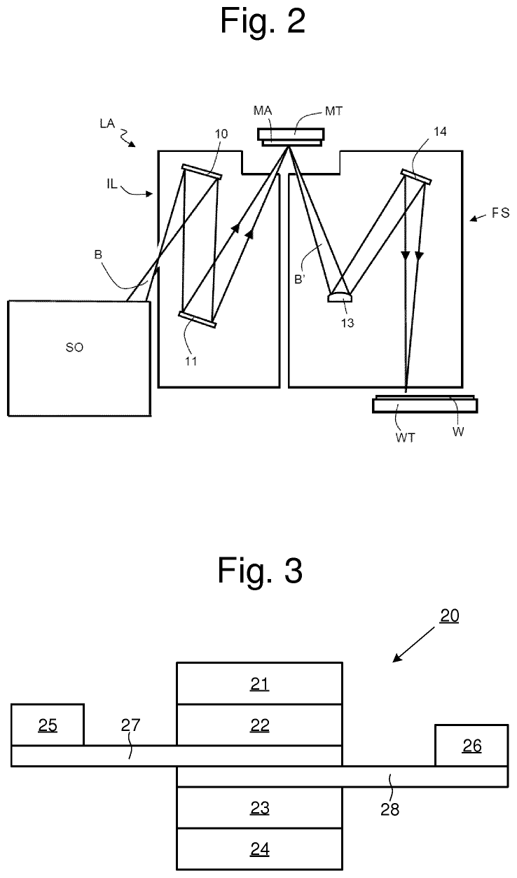

FIG. 2 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 2, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

FIG. 3 is a schematic side view of a tunnelling FET 20. The tunnelling FET 20 comprises a vertical stack of layers comprising a top gate 21, an upper dielectric layer 22, a lower dielectric layer 23 and a bottom gate 24. A source 25 and a drain 26 are respectively connected to the vertical stack of layers by two-dimensional layers 27 and 28. Each of the two-dimensional layers 27 and 28 may consist of a layer that is one atomic thick, which may also be referred to as a monolayer or single atomic layer. Either or both of the two-dimensional layers 27 and 28 may be formed from MoS₂ or hexagonal-BN for example. Manufacture of the tunnelling FET 20 requires patterning of the two-dimensional layers 27 and 28 in the lateral direction. As mentioned in the introductory part of the description, the patterning can be performed using lithography applied to a photo-resist, but this approach can introduce defects. Embodiments of the present disclosure provide an alternative approach for forming a patterned layer of material. Embodiments can be used for manufacturing at least one monolayer (e.g. one or both of the two-dimensional layers 27 and 28) of a tunnelling FET or for manufacturing other semiconductor devices or for manufacturing devices which are not semiconductor devices.

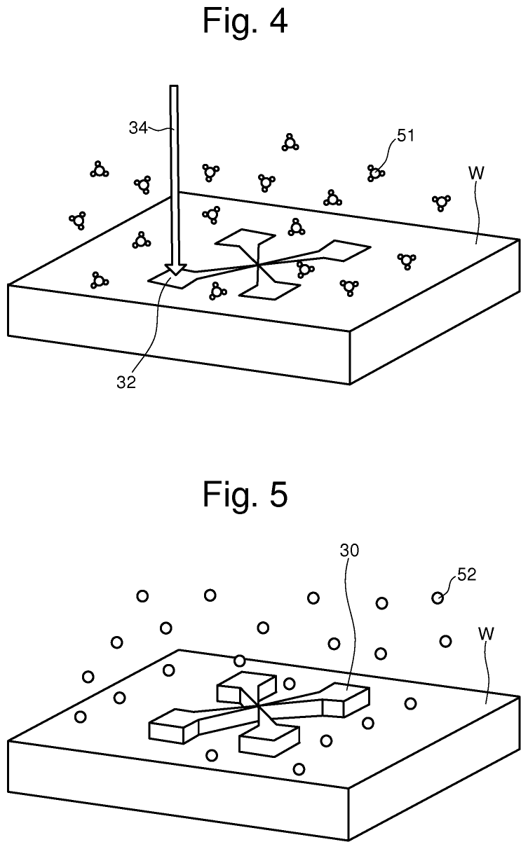

FIGS. 4 and 5 schematically depict formation of a patterned layer of material 30 according to a method of an embodiment. As depicted in FIG. 4, the method comprises irradiating 34 a selected portion 32 of a surface of a substrate W during a deposition process. In an embodiment, the deposition process comprises, consists essentially of, or consists of an atomic layer deposition process. The irradiation locally drives the deposition process (e.g. atomic layer deposition) in the selected region 32 and thereby causes the deposition process (e.g. atomic layer deposition) to form a layer of material 30 (see FIG. 5) in a pattern defined by the selected portion 32. A pattern is thus formed without needing any resist. No processing to remove a resist is therefore required, which reduces the risk of damage to the patterned layer of material 30. In contrast to traditional lithography-based semiconductor manufacturing processes, instead of being used to break or cross-link molecules in a resist, in embodiments of the present disclosure radiation is being used to drive a chemical reaction involved in a deposition process (e.g. atomic layer deposition process).

In this embodiment, the irradiation is performed with radiation comprising, consisting essentially of, or consisting of any type of EUV radiation (having a wavelength less than 100 nm) that is capable of locally driving the deposition process (e.g. atomic layer deposition process). The use of EUV radiation provides high spatial resolution. In some other embodiments, the irradiation is performed with radiation comprising, consisting essentially of, or consisting of, higher wavelength radiation in combination with an immersion liquid, as described below. The higher wavelength radiation may be in the range of 100 nm to 400 nm (including DUV radiation).

Atomic layer deposition is a known thin-film deposition technique in which each of at least two chemicals (which may be referred to as precursor materials) are made to react with the surface of a material in a sequential, self-limiting, manner. In contrast to chemical vapor deposition, the two precursor materials are never present simultaneously above the substrate W.

In embodiments of the present disclosure, the atomic layer deposition comprises at least a first step and a second step. In the first step, an example of which is depicted in FIG. 4, a first precursor material 51 is made to react with a surface of a substrate W. In the second step, an example of which is depicted in FIG. 5, a second precursor material 52 is made to react with the substrate W in a region where the first precursor 51 reacted with the substrate W in the first step (in this example the selected regions 32).

In the example of FIGS. 4 and 5, the substrate W is irradiated in the first step only. In other embodiments, the irradiation of the selected portion 32 is performed during the second step only or during the first step and the second step. In embodiments not involving immersion liquid, the irradiation of the selected portion 32 in at least one of the two steps is performed using EUV radiation. Irradiation may additionally be performed in one or more other steps using other forms of irradiation (with or without an immersion liquid), including DUV radiation.

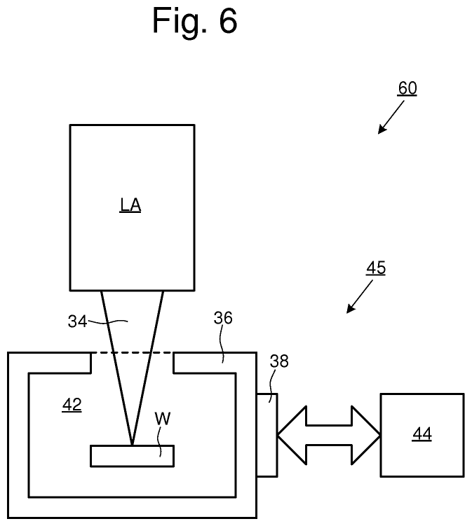

FIG. 6 schematically depicts an apparatus 60 for performing the method. The apparatus 60 thus forms a patterned layer of material. The apparatus 60 comprises an irradiation system. The irradiation system may comprise a lithographic apparatus LA. The lithographic apparatus LA irradiates the selected portion 32 by projecting a patterned radiation beam from a patterning device MA onto the substrate W. The lithographic apparatus LA may be configured as described above with reference to FIG. 1 (e.g. when the irradiation comprises DUV radiation and/or immersion lithography is required) or as described above with reference to FIG. 2 (e.g. when the irradiation comprises EUV radiation).

In an embodiment, the lithographic apparatus LA is configured to perform immersion lithography. In such an embodiment, the deposition process (e.g. atomic layer deposition process) may comprise a step in which the selected portion 32 is irradiated while the selected portion 32 is in contact with an immersion liquid. Thus, for example, the deposition process (e.g. atomic layer deposition process) may comprise a first step comprising adsorption of a precursor from a gaseous precursor material to the substrate W and a second step in which the adsorbed precursor is modified in the selected portion 32 (e.g. to remove a by-product of the adsorption process) by irradiation through the immersion liquid. Any by-product produced by the irradiation through the immersion liquid can conveniently be carried away by flow of the immersion liquid. In an embodiment, the irradiated substrate W is subsequently dried and any further required processing is performed on the dried substrate W.

In an embodiment, an environment control system 45 is provided. The environment control system 45 allows the composition of the environment 42 above the substrate W to be controlled in such a way as to allow the deposition process (e.g. atomic layer deposition process) to proceed. In an embodiment, the environment control system 45 comprises a chamber 36 to provide a sealed environment 42 including the selected portion 32 of the surface of the substrate W. In some embodiments, all of the substrate W will be within the chamber 36 during the deposition process (e.g. atomic layer deposition process). In an embodiment, a materials exchange system 38 (e.g. a port into the chamber 36 and associated valves and/or conduits) is provided that allows materials to be added to and removed from the sealed environment 42 to allow different compositional environments to be established within the sealed environment 42. Materials may be provided to and from the materials exchange system 38 by a flow manager 44. The flow manager 44 may comprise any suitable combination of reservoirs, ducting, valves, sinks, pumps, control systems, and/or other components necessary to provide the required flows of materials into and out of the chamber 36. The different compositional environments achieved in this way correspond to different respective stages of an atomic layer deposition process. In some embodiments, the materials added to and removed from the chamber 36 are gaseous, thereby providing compositional environments consisting of different combinations of gases. In an embodiment in which one or more steps of an atomic layer deposition process are performed by irradiating the substrate W through an immersion liquid, the environment control system 45 may be configured to allow switching between a state in which a controlled liquid environment is maintained above the substrate W (e.g. during exposure in an immersion lithography mode) and a state in which a controlled gaseous environment is maintained above the substrate W (e.g. during adsorption of a precursor from a gaseous precursor material).

In some embodiments, the driving of the deposition process (e.g. atomic layer deposition process) in the selected portion 32 comprises driving a chemical reaction involving a precursor material. The precursor material will be provided as part of the compositional environment established above the substrate during the irradiation. The driving of the chemical reaction may cause the chemical reaction to proceed at a faster rate than would be the case in the absence of the irradiation. Alternatively, the chemical reaction may be such that it would not occur at all in the absence of the irradiation. In an embodiment, the chemical reaction is endothermic and the irradiation provides the energy necessary to allow the chemical reaction to proceed. In some embodiments, the chemical reaction is at least partially driven by heat generated in the substrate W by the irradiation. Thus, the chemical reaction being driven by the irradiation may comprise a chemical reaction that requires an elevated temperature to proceed or which proceeds more rapidly at elevated temperatures. In some embodiments, the chemical reaction comprises a photochemical reaction driven by the irradiation. Thus, at least one species involved in the chemical reaction directly absorbs a photon from the irradiation and the absorption of the photon allows the chemical reaction to proceed. In some embodiments, the photochemical reaction comprises a multi-photon photochemical reaction involving absorption of two or more photons by each of at least one species involved in the photochemical reaction. The requirement for two or more photons to be absorbed makes the chemical reaction much more sensitive to variations in the intensity of the irradiation (i.e. the rate of the chemical reaction varies much more strongly as a function of intensity) than would be the case for single photon photochemical reactions. The increased sensitivity to intensity provides improved lateral contrast. In an embodiment, a combination of a photochemical reaction and radiation induced heating is used to provide a well-defined process window in which the chemical reaction is driven locally to produce the pattern. In some embodiments, the substrate W can be additionally or alternatively heated or cooled externally (i.e. not by radiation) to provide the well-defined process window.

In an embodiment, the irradiation drives an endothermic chemical reaction in a precursor material comprising, consisting essentially of, or consisting of, Mo(thd)₃, where thd=2,2,6,6-tetramethylheptane-3,5-dionato. The irradiation causes deposition of Mo in the selected region 32. Mo is not deposited outside of the selected region 32. This chemical reaction is an example of a two-photon photochemical reaction. A high contrast patterned layer of Mo can therefore be achieved. Subsequent steps of the atomic layer deposition process can be performed as desired to build up the material of interest in a shape defined by the irradiation (i.e. above the selected region 32 and not elsewhere). A further material may be grown on the layer of Mo for example. In an embodiment, the further material comprises S. A patterned monolayer of MoS₂ can therefore be formed. The patterned monolayer of MoS₂ may be used in a tunnelling FET, for example, as described above.

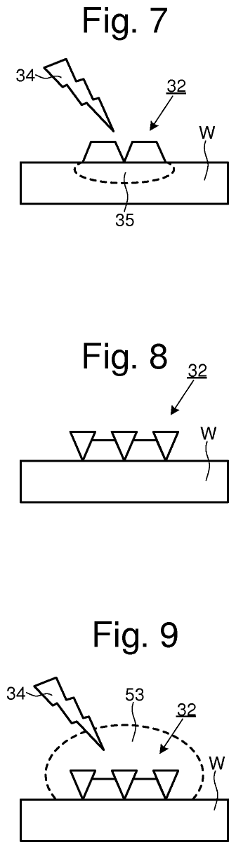

In an embodiment, the chemical reaction comprises a pyrolytic process involving dissociation of the precursor material adsorbed to the selected region 32. Steps in an embodiment of this type are schematically depicted in FIGS. 7 and 8. This embodiment is an example of a situation where the chemical reaction is at least partially driven by heat 35 generated in the substrate W by the irradiation 34. As depicted in FIG. 7, the heat 35 causes dissociation of molecules of the precursor material exclusively in the selected region 32 during a first step of an atomic layer deposition process. A patterned layer of material is thus provided. FIG. 8 shows a subsequent step of the atomic layer deposition process in which material in the selected region 32 (and no other region) is modified. The subsequent step may comprise oxidation or reduction, for example, of the patterned layer of material formed in the first step.

In an embodiment, the driving of the chemical reaction comprises generating a reactive species 53 by the radiation locally interacting with a gas above the selected region 32. An example of such an interaction is depicted schematically in FIG. 9. In an embodiment, the generated reactive species 53 comprises an oxidizing agent or a reducing agent. The generated reactive species may comprise ozone formed from O₂, using DUV irradiation for example. Alternatively, the generated reactive species 53 may comprise dissociated H₂O formed for example by irradiating water vapor with UV radiation. Alternatively, the generated reactive species 53 may comprise dissociated NH₃. Atomic layer deposition chemical reactions which only occur when the reactive species is present can thus be driven to occur only in the selected region 32 defined by the irradiation. Although these processes may use DUV radiation, if other steps in the method use EUV radiation, even higher spatial resolution than is possible using DUV only may be achieved.

In an embodiment, the atomic layer deposition process comprises one or more of the following reactions:

BBr₃+NH₃ to create BN

Zn(OC₂H₅)₂+H₂O to create ZnO

Ta(OC₂H₅)₂+H₂O to create Ta₂O₅

Ta(OC₂H₅)₅₊₀₂ to create Ta₂O₅

Al(CH₃)₃+O₂ to create Al₂O₃

Ti(OCH(CH₃)₂)₄+O₂ to create TiO₂

In each of the above six example reactions, the first component comprises a precursor material in gaseous form and the second component comprises an oxidizer. All of these reactions are photoactive.

For the NH₃ based reaction, the atomic layer deposition process may comprise a step of irradiating the NH₃, for example using an excimer laser, to dissociate the NH₃ (the same excimer laser may also be used in this case to dissociate the precursor material BBr₃). A patterned monolayer of hexagonal-BN can therefore be formed. The patterned monolayer of hexagonal-BN may be used in a tunnelling FET, for example, as described above.

For the H₂O based reactions, the atomic layer deposition process may comprise a step of irradiating water vapor using UV radiation to dissociate the water vapor. For the O₂ based reactions, the atomic layer deposition process may comprise a step of irradiating O₂ with DUV radiation to produce ozone.

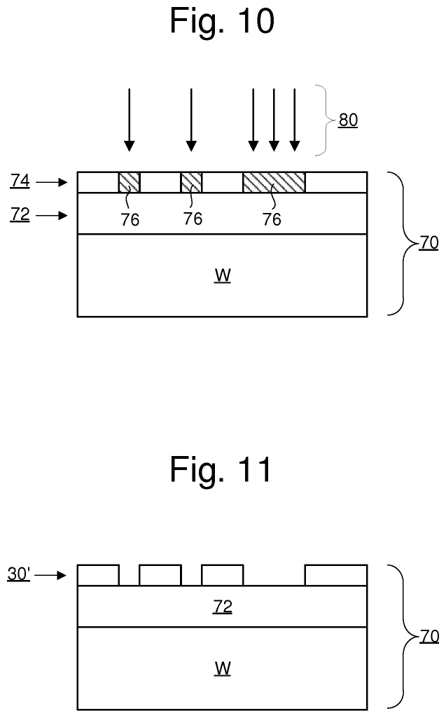

FIGS. 10 and 11 schematically depict formation of a patterned layer of material 30′ according to a method of an embodiment. As depicted in FIG. 10, the method comprises providing a stack 70. The stack 70 comprises a substrate W and a monolayer of material 74. One or more intermediate layers 72 may optionally be provided between the substrate W and the monolayer of material 74. The stack 70 is processed to remove material in one or more selected regions 76 of the monolayer of material 74. In the embodiment shown, the removal of material applies a pattern to the monolayer of material 74. In embodiments where the monolayer of material 74 already contains a pattern, the removal of material modifies a pattern in the monolayer of material 74. Thus, where the monolayer of material 74 comprises a patterned layer of material 30 formed by any of the methods described above with reference to FIGS. 3-9, for example, the method of the present embodiment can be used to modify the pattern to provide a new pattern.

The monolayer of material 74 may be provided using various techniques. In an embodiment, the monolayer of material 74 is formed using an atomic layer deposition process. In an embodiment, the monolayer of material 74 comprises, consists essentially of, or consists of, one or more of the following in any combination: MoS₂, hexagonal-BN, BN, ZnO, Ta₂O₅, Al₂O₃, TiO₂. The monolayer of material 74 may alternatively or additionally comprise other materials.

In an embodiment, the removal of material is performed by selectively irradiating material (e.g. such that the radiation interacts directly with the material) in the one or more selected regions 76. FIG. 10 depicts a stack 70 in the process of being irradiated by a patterned radiation beam 80. Material in the selected regions 76 is disturbed by the irradiation. The disturbance is a stage in a process that will result in material in the selected regions 76 being removed. FIG. 11 depicts the stack 70 after the removal process has been completed, with gaps in the monolayer of material 74 defining a pattern in the monolayer of material 74. The monolayer of material 74 becomes a patterned layer of material 30′. Interaction between the incident radiation and material in the selected regions 76 causes the removal, but various mechanisms may contribute.

In one class of embodiments, the removal of material occurs by laser ablation. Laser ablation is known for use in drilling or cutting materials, typically metals. The inventors have found that laser parameters can be tuned in such a way as to achieve a level of control that is suitable for patterning monolayers of material 74 such as those considered in the present disclosure. The tuning of laser parameters may comprise tuning of one or more of the following: fluence, pulse length, repetition rate, pulse shape, and wavelength. In an embodiment, the laser is configured to operate with a pulse length shorter than 10⁻¹¹s, optionally shorter than 10¹²s, optionally shorter than 10¹³s, optionally shorter than 10¹⁴s, optionally shorter than 10⁻¹⁵s. The use of laser ablation improves throughput relative to conventional lithography-based patterning approaches because the patterning and removal of material is performed in a single step. The laser for performing the laser ablation can be provided as a stand-alone device or integrated into a lithography apparatus of the type described above with reference to FIGS. 1 and 2.

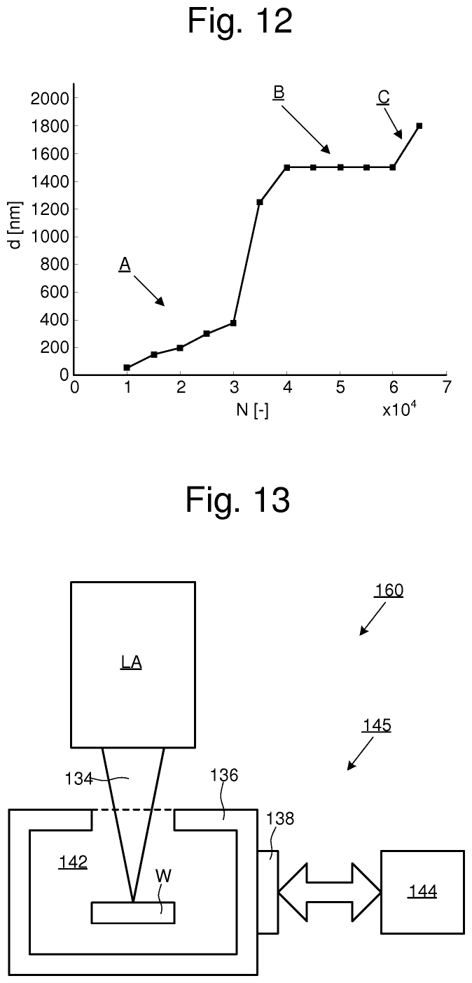

FIG. 12 is a graph demonstrating a degree of control that is possible using laser ablation. The vertical axis represents depth of cutting using laser ablation into a layer of amorphous carbon on top of SiN. The horizontal axis represents the number of laser pulses applied, N, in units of 10⁴. In this example an infrared laser was used with a pulse length of 400 fs and fluence of about 100 mJ/cm². FIG. 12 shows that an average rate of removal of 0.03 nm per pulse was observed, with clear differences in the rate of laser ablation as the process penetrates through different layers. In regime A, the laser ablation progressively cuts through the amorphous carbon layer to a depth of 1.5 microns. In regime B, the laser ablation slows abruptly when an interface between the amorphous carbon layer and the SiN is reached. By continuing to apply pulses, the laser ablation eventually (after an additional 20000 pulses) breaks through the interface and into the SiN layer (regime C). Thus, by controlling the number of pulses applied it is possible to reliably control cutting through material to a desired depth (e.g. with a 0.03 nm depth of removal per pulse), particularly where it is desired that the cutting stop accurately at an interface between two different materials. In the example shown, applying 50000 pulses will reliably cut through 1.5 microns of material to the precise location of an interface between two layers, but the approach is applicable to any depth of the material being cut through (fewer pulses in regime A would be necessary for thinner layers). Due to the prolonged slowing down of the laser ablation process when the interface is reached, which facilitates stopping of the ablation process before the material below the interface is damaged, the method can be applied to cut precisely through arbitrarily thin layers without damage to underlying layers, including through monolayers of material 74 as depicted in FIGS. 10 and 11.

In another class of embodiments, the removal of material occurs by a chemical reaction between the material and an environment. The chemical reaction is driven by the irradiation. The chemical reaction may be a photochemical reaction. In an embodiment, the radiation driving the chemical reaction comprises, consists essentially of, or consists of EUV radiation (having a wavelength less than 100 nm). The use of EUV radiation provides high spatial resolution. The use of EUV radiation also allows the methodology to be implemented by EUV lithography apparatus. In other embodiments, longer wavelength radiation, such as DUV, may be used. In an embodiment, the driving of the chemical reaction comprises generating a reactive species by the radiation locally interacting with a gaseous environment. In an embodiment, the generated reactive species comprises an oxidizing agent or a reducing agent.

FIG. 13 schematically depicts an apparatus 160 for performing the method. The apparatus 160 thus forms a patterned layer of material. The apparatus 160 comprises an irradiation system. The irradiation system may comprise a lithographic apparatus LA. The lithographic apparatus LA irradiates the one or more selected regions 76 of the monolayer of material 74 by projecting a patterned radiation beam 134 from a patterning device MA onto the substrate W. The lithographic apparatus LA may be configured as described above with reference to FIG. 1 (e.g. when the irradiation comprises DUV radiation and/or immersion lithography is required) or as described above with reference to FIG. 2 (e.g. when the irradiation comprises EUV radiation).

In an embodiment, the lithographic apparatus LA is configured to perform immersion lithography. In such an embodiment, the one or more selected regions 76 of the monolayer of material 74 may be irradiated while in contact with an immersion liquid. Material removed by the irradiation may conveniently be carried away by flow of the immersion liquid. In an embodiment, the irradiated substrate W is subsequently dried and any further required processing is performed on the dried substrate W.

In an embodiment, an environment control system 145 is provided. The environment control system 145 allows the composition of the environment 142 above the substrate W to be controlled. In an embodiment, the environment control system 145 comprises a chamber 136 to provide a sealed environment 142 including the one or more selected regions 76 of the monolayer of material 74. In some embodiments, all of the substrate W will be within the chamber 36 during the formation of the patterned layer of material. In an embodiment, a materials exchange system 138 (e.g. a port into the chamber 136 and associated valves and/or conduits) is provided that allows materials to be added to and removed from the sealed environment 142 to allow different compositional environments to be established within the sealed environment 142. Materials may be provided to and from the materials exchange system 138 by a flow manager 144. The flow manager 144 may comprise any suitable combination of reservoirs, ducting, valves, sinks, pumps, control systems, and/or other components necessary to provide the required flows of materials into and out of the chamber 136. The different compositional environments achieved in this way may correspond to different respective stages of an atomic layer deposition process used to form the monolayer of material 74 prior to the formation of the patterned layer of material, as well as to a stage during which the patterned layer of material is formed. In some embodiments, the materials added to and removed from the chamber 136 are gaseous, thereby providing compositional environments consisting of different combinations of gases. In an embodiment in which one or more steps are performed by irradiating the substrate W through an immersion liquid, the environment control system 145 may be configured to allow switching between a state in which a controlled liquid environment is maintained above the substrate W (e.g. during exposure in an immersion lithography mode) and a state in which a controlled gaseous environment is maintained above the substrate W (e.g. when the patterned layer of material is being formed).

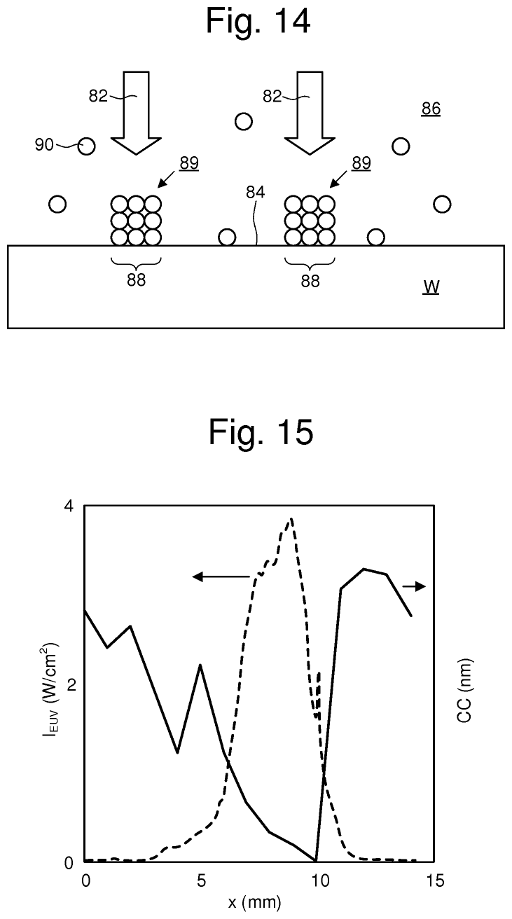

In a further class of embodiments, the driving of the deposition process occurs at least partly via the generation of secondary electrons by interaction between incident EUV radiation 82 and the substrate W, as depicted schematically in FIG. 14. In such embodiments, secondary electrons are generated in the bulk of the substrate W (i.e. beneath a surface 84 of the substrate W). Some of the secondary electrons will have sufficient energy to leave the substrate W via the surface 84 and enter a space 86 above the substrate W (i.e. on the side of the substrate W from which the EUV radiation 82 is incident on the substrate W). In embodiments where the substrate W is a silicon wafer, it is expected that the secondary electrons will typically have energies spread between 0 eV and about 20 eV (with an average of about 10 eV), compared with a typical work function of about 5 eV.

The space 86 above the substrate W is controlled (e.g. by an environment control system 45, 145 as described above) to comprise precursor material 90 (e.g. as a vapor). In an embodiment, the precursor material 90 comprises one or more carbon containing compounds, for example, where it is desired to deposit carbon onto the substrate W. A portion of the secondary electrons that have left the substrate W interact with the precursor material 90. The interaction with the precursor material 90 may modify the precursor material 90 to promote deposition of material derived from the precursor material 90 on the substrate W. The modification of the precursor material 90 may comprise ionization of the precursor material 90. In the case where it is desired to deposit carbon, for example, the modification of the precursor material 90 may comprise formation of carbon ions near the surface 84, which promotes growth of carbon clusters on the surface 84.

The promotion of deposition of material by the secondary electrons occurs predominantly or exclusively in regions 88 irradiated by the EUV radiation 82. Spatial patterns can be defined with high definition using EUV radiation 82. Combining this capability with the local nature of the promotion of deposition by the secondary electrons allows patterned layers of deposited material to be formed with high accuracy.

In an embodiment, the promotion of deposition of material comprises promotion of deposition of material on the surface 84 and on deposited material 89 that has already been deposited on the surface 84. In this way, the process can deposit monolayers of material as well as thicker layers, as required.

In an embodiment, the EUV radiation 82 interacts with gas above the substrate W to generate a plasma. In an embodiment, the interaction with gas comprises ionization of hydrogen. In an embodiment, the plasma provides an etching function. Plasma etching is known in the art and can be used to clean unwanted build-up of material (particularly carbon and tin) on mirrors of EUV lithography apparatus. The inventors have found, however, that where the plasma is produced by EUV radiation, the etching is surprisingly less effective in regions of surfaces that are being irradiated directly (i.e. within the EUV spot). Without wishing to be bound by theory, it is believed the protective effect may arise due to the EUV radiation inducing deposition of material in the irradiated regions at a faster rate than material is removed by plasma etching. Alternatively or additionally, the EUV radiation may cause chemical changes, bond formation, and/or phase changes such as (partial) crystallization that resist the plasma etching. The combination of plasma etching outside of irradiated regions 88 and promotion of deposition of material within irradiated regions 88 allows patterns of deposited material to be deposited with high reliability and with minimal or no unwanted deposition of material outside of irradiated regions 88. FIG. 15 is a graph showing example results from an experiment demonstrating the protective effect of EUV irradiation. The experiment comprised irradiating a substrate W with EUV radiation 82 in a region 88, as described above, in a case where the substrate W had a layer of carbon material already deposited on it and where the EUV generated a plasma from hydrogen in the space 86 above the substrate W. The horizontal axis represents a range of positions along a line on the substrate W passing through the irradiated region 88. The left-hand vertical axis and broken line curve represent variation with position of an intensity of incident EUV radiation 82 I_{EUV}. The broken line curve thus defines the location of the region 88: namely between about 6 mm and 10 mm. The right-hand vertical axis and solid line curve represent variation of an effectiveness of a carbon cleaning (CC) process mediated by a hydrogen plasma generated by the EUV radiation 82. The effectiveness of a carbon cleaning process (represented in this example by a depth in nm of material removed) is seen to diminish markedly in the region 88 being irradiated by EUV radiation 82. The EUV radiation 82 thus locally protects the layer of carbon against etching by the EUV generated plasma.

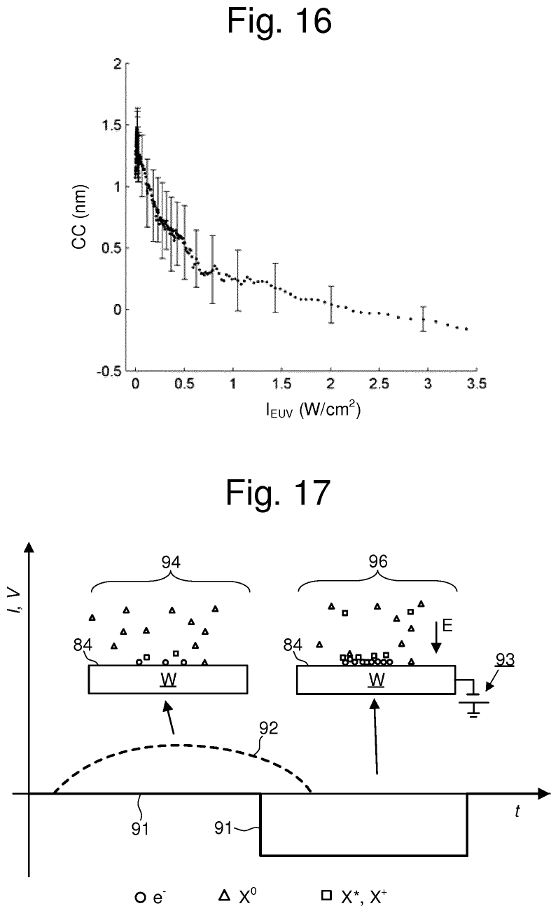

FIG. 16 is a graph showing example results from an experiment further demonstrating protection by the EUV radiation 82 against etching by the EUV generated plasma. In this case, the graph plots variation of the effectiveness of a carbon cleaning process (CC) (vertical axis) against the intensity of incident EUV radiation 82 I_{EUV} (horizontal axis). The protective effect is seen to increase rapidly with increasing intensity of incident EUV radiation 82 I_{EUV} up to about 1 W/cm². Above 1 W/cm², the protective effect increases in strength less quickly with increasing intensity of incident EUV radiation 82 I_{EUV}.

Behaviour analogous to that discussed above and demonstrated in FIGS. 15 and 16 has been observed with tin instead of carbon, and the underlying mechanism is expected to apply to a wide range of other materials. By appropriate choice of precursor material 90 (e.g. as combination of gases with a given ratio) it is possible to selectively deposit a correspondingly wide range of materials using the same approach. For example, the approach may be used for selective deposition of graphene, hBN, transition metal chalcogenides (necessary for future FETs, photonics and optoelectronics devices and leads).

In a further class of embodiment, as depicted schematically in FIG. 17, an electrical field E is applied above the substrate W. The electric field E forces the secondary electrons away from the substrate W. In an embodiment, the electric field E is substantially perpendicular to the surface 84 of the substrate W. In an embodiment, the electric field E is applied by an electric field controller 93. In an embodiment, the electric field controller 93 comprises an electrical circuit that raises an electrical potential of the substrate W relative to ground (i.e. applies a voltage to the substrate W).

The electric field E provides improved yield and improved pattern definition (sharpness). Without wishing to be bound by theory, it is believed these effects may arise due to one or more of the following mechanisms. Firstly, by encouraging movement of secondary electrons into the space 86 above the substrate W, the electric field E promotes increased interaction between the secondary electrons and the precursor material 90, thereby increasing yield. Secondly, precursor material that has been ionized by the secondary electrons may be encouraged by the electric field E to move quickly and directly towards the substrate, thereby promoting efficient and localised deposition. Thirdly, particularly when the electric field E is oriented perpendicularly relative to the surface 84, the electric field reduces lateral spread of the secondary electrons and ionized precursor material, thereby favouring sharper edges in the pattern formed by the deposition process.

In the example of FIG. 17, a variation of an intensity I of the EUV radiation 82 as a function of time t is represented schematically by broken line curve 92, and a voltage applied to the substrate W as a function of time t is depicted by the solid line curve 91. Secondary electrons e⁻ are represented schematically by circles. Precursor material X⁰ that has not been modified by EUV radiation 82 is represented by triangles. Precursor material X* and X+ that has been modified (e.g. by ionization) by EUV radiation 82 is represented by squares. Sub-diagram 94 is a schematic side view of a substrate W during a time period when EUV radiation 82 is being applied without an electric field. Sub-diagram 96 is a schematic side view of the same substrate W during a time period when EUV radiation 82 is being applied with an electric field. Sub-diagram 96 schematically illustrates how the electric field E might improve yield and pattern definition, with large numbers of secondary electrons being driven away from the surface 84 in a laterally localized region, promoting increased generation of modified precursor material in the laterally localized region.

The above-described local suppression of plasma etching can be exploited to provide controlled etching of a pre-existing layer of material. In an embodiment, a method is provided in which a stack comprising a substrate W and a layer of material on the substrate W is irradiated in one or more selected regions by EUV radiation. The irradiation applies a pattern to the layer of material. If the layer of material already comprises a pattern, the irradiation may modify the pattern. The irradiation removes material by generating a plasma in the region 86 above the substrate W, as described above. The plasma may be generated by ionizing hydrogen for example. The radiation interacts with the substrate W to locally suppress (or prevent) the removal of material in the one or more selected regions (as described above with reference to FIGS. 15 and 16 for example) relative to other regions. The other regions are regions that are not being irradiated and where suppression of the cleaning effect is not observed.

The precursor material 90 referred to above with reference to the embodiments of FIGS. 14-17 may comprise any of the precursor materials 90 discussed above in relation to earlier embodiments. In an embodiment the precursor material 90 comprises carbon or a carbon compound. In such an embodiment, the material being deposited (or selectively etched) may comprise carbon or a carbon compound. In an embodiment the precursor material 90 comprises tin or a tin compound. In such an embodiment, the material being deposited (or selectively etched) may comprise tin or a tin compound. The mechanism is expected to be applicable to a wide range of other materials. Where plasma etching is required, a suitable plasma-promoting material such as hydrogen may be provided. The relative concentrations and compositions of plasma-promoting materials and/or precursor materials may be tuned to optimize yield and/or patterning quality.

The embodiments may further be described using the following clauses:

1. A method of forming a patterned layer of material, comprising:

irradiating a selected portion of a surface of a substrate with electromagnetic radiation having a wavelength of less than 100 nm during a deposition process, the irradiation being such as to locally drive the deposition process in the selected region and thereby cause the deposition process to form a layer of material in a pattern defined by the selected portion.

2. The method of clause 1, wherein the driving of the deposition process in the selected portion comprises driving a chemical reaction involving a precursor material.
3. The method of clause 2, wherein the chemical reaction comprises a photochemical reaction driven by the irradiation.
4. The method of clause 3, wherein the photochemical reaction is a multi-photon photochemical reaction involving absorption of two or more photons by each of at least one species involved in the photochemical reaction.
5. The method of clause 4, wherein the multi-photon photochemical reaction is a two-photon photochemical reaction.
6. The method of any of clauses 2 to 5, wherein the precursor material comprises Mo(thd)₃, where thd=2,2,6,6-tetramethylheptane-3,5-dionato.
7. The method of any of clauses 2 to 6, wherein the chemical reaction is at least partially driven by heat generated in the substrate by the irradiation.
8. The method of clause 7, wherein the chemical reaction comprises a pyrolytic process involving dissociation of the precursor material adsorbed to the selected region.
9. The method of any of clauses 2 to 8, wherein the precursor material comprises one or more of the following: BBr₃, Zn(OC₂H₅)₂, Ta(OC₂H₅)₂, Ta(OC₂H₅)₅, Al(CH₃)₃, Ti(OCH(CH₃)₂)₄.
10. The method of any of clauses 2 to 9, wherein the driving of the chemical reaction comprises generating a reactive species by the radiation locally interacting with a gas above the selected region.
11. The method of clause 10, wherein the generated reactive species comprises an oxidising agent or a reducing agent.
12. The method of clause 10 or 11, wherein the generated reactive species comprises one or more of the following: dissociated O₂, dissociated H₂O, dissociated NH₃.
13. The method of any of clauses 1-12, wherein the driving of the deposition process comprises generating secondary electrons by interaction between the electromagnetic radiation and the substrate.
14. The method of clause 13, wherein a portion of the secondary electrons leave the substrate and interact with precursor material above the substrate, the interaction between the secondary electrons and the precursor material being such as to promote deposition of material derived from the precursor material.
15. The method of clause 14, further comprising applying an electric field that forces secondary electrons away from the substrate.
16. The method of clause 15, wherein the force is directed perpendicularly relative to the surface of the substrate.
17. The method of any of clauses 13-16, wherein the precursor material and the layer of material deposited by the deposition process comprise one or more of the following: carbon or a carbon compound, tin or a tin compound.
18. The method of any preceding clause, wherein the deposition process comprises an atomic layer deposition process.
19. The method of clause 18, wherein the atomic layer deposition process comprises two steps and the irradiation of the selected portion of the surface of the substrate is performed during either or both of the two steps.
20. The method of clause 19, wherein at least one of the steps comprises irradiating the selected portion of the substrate while the selected portion of the substrate is in contact with a liquid.
21. A method of forming a patterned layer of material, comprising:

providing a stack comprising a substrate and a layer of material; and

irradiating one or more selected regions of the layer of material with electromagnetic radiation having a wavelength of less than 100 nm to apply a pattern to the layer of material or modify a pattern in the layer of material, wherein:

the irradiation causes removal of material during the irradiation by generating a plasma in the region above the substrate; and

the radiation interacts with the substrate to locally suppress the removal of material in the one or more selected regions relative to other regions in order to apply the pattern or modify the pattern.

22. The method of any of clauses 1 to 21, wherein the electromagnetic radiation has a wavelength in the range of 4 nm to 20 nm.
23. A method of forming a patterned layer of material, comprising:

irradiating a selected portion of a surface of a substrate with electromagnetic radiation during an atomic layer deposition process, the irradiation being such as to locally drive the atomic layer deposition process in the selected region and thereby cause the atomic layer deposition process to form a layer of material in a pattern defined by the selected portion, wherein:

the atomic layer deposition process comprises two steps and the irradiation of the selected portion is performed during at least one of the two steps and while the selected portion of the substrate is in contact with a liquid.

24. The method of any preceding clause, further comprising:

processing the layer of material formed in a pattern to remove material in one or more selected regions, thereby modifying the pattern.

25. The method of clause 24, wherein the removal of material is performed by selectively irradiating the material in the one or more selected regions.
26. A method of forming a patterned layer of material, comprising:

providing a stack comprising a substrate and a monolayer of material; and

processing the stack to remove material in one or more selected regions of the monolayer of material by selectively irradiating the material in the one or more selected regions, thereby applying a pattern to the monolayer of material or modifying a pattern in the monolayer of material.

27. The method of clause 25 or 26, wherein the material is removed in the one or more selected regions during the selective irradiation.
28. The method of any of clauses 25-27, wherein the removal of material occurs by laser ablation.
29. The method of any of clauses 25-28, wherein the removal of material occurs by a chemical reaction between the material and an environment, the chemical reaction being driven by the irradiation.
30. The method of clause 29, wherein the radiation driving the chemical reaction comprises radiation having a wavelength lower than 100 nm.
31. A method of forming a semiconductor device, comprising using the method of any of clauses 1 to 30 to form at least one layer in the device.
32. The method of clause 31, wherein the semiconductor device comprises a tunnelling FET and the method of any of clauses 1 to 30 is used to form at least one monolayer of the tunnelling FET.
33. An apparatus for forming a patterned layer of material, comprising:

an irradiation system configured to irradiate a selected portion of a surface of a substrate with electromagnetic radiation having a wavelength of less than 100 nm during a deposition process; and

an environment control system configured to allow the composition of the environment above the substrate to be controlled in such a way as to allow the deposition process to proceed.

34. An apparatus for forming a patterned layer of material, comprising:

an irradiation system configured to irradiate a selected portion of a surface of a substrate with electromagnetic radiation during a deposition process; and

an environment control system configured to allow the composition of the environment above the substrate to be controlled in such a way as to allow the deposition process to proceed, wherein the environment control system is configured to allow a liquid to be maintained in contact with the selected portion during irradiation of the selected portion in at least one step of the deposition process.

35. The apparatus of clause 33 or 34, wherein the environment control system comprises:

a chamber to provide a sealed environment including the selected portion of the surface of the substrate; and

a materials exchange system configured to allow materials to be added to and removed from the sealed environment to allow different compositional environments to be established within the sealed environment, the different compositional environments corresponding to different respective steps of the deposition process.

36. The apparatus of any of clauses 33-35, wherein:

the environment control system is configured to control the environment above the substrate to provide a precursor material in the environment;

the control of the environment is such that a portion of secondary electrons generated by interaction between the electromagnetic radiation and the substrate interact with the precursor material in the environment; and the interaction between the secondary electrons and the precursor material is such as to promote deposition of material derived from the precursor material.

37. The apparatus of any of clauses 33-36, further comprising:

an electric field controller configured to apply an electric field that is oriented so as to force secondary electrons away from the substrate.

38. The apparatus of clause 37, wherein the electric field controller is configured so that the electric field is directed perpendicularly relative to the surface of the substrate.
39. The apparatus of clause 37 or 38, wherein the electric field controller is configured to apply the electric field by applying a voltage to the substrate.
40. An apparatus for forming a patterned layer of material, comprising:

an irradiation system configured to irradiate one or more selected regions of a layer of material on a substrate with electromagnetic radiation having a wavelength of less than 100 nm; and

an environment control system configured to allow the composition of the environment above the substrate to be controlled during the irradiation, wherein:

the environment control system is configured to control the environment to provide a plasma-promoting material in the environment;

the plasma-promoting material is such as to cause a plasma to be generated by the electromagnetic radiation as the electromagnetic radiation passes through the controlled environment;

the plasma is such as to cause removal of material in the layer of material during the irradiation; and

the radiation interacts with the substrate to locally suppress the removal of material in the one or more selected regions relative to other regions, thereby applying a pattern to the layer of material or modifying a pattern in the layer of material.

41. An apparatus for forming a patterned layer of material, comprising:

an irradiation system configured to selectively irradiate one or more selected regions of a monolayer of material with electromagnetic radiation having a wavelength of less than 100 nm; and

an environment control system configured to allow the composition of the environment above the substrate to be controlled in such a way as to cause removal of material in the one or more selected regions of the monolayer of material by a chemical reaction between the material and the controlled environment, the chemical reaction being driven by the irradiation.

42. The apparatus of any of clauses 33 to 41, wherein the irradiation system comprises a lithographic apparatus configured to provide the irradiation by projecting a patterned radiation beam from a patterning device onto the substrate.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A method for forming a patterned layer of material, the method comprising:
irradiating a selected portion of a surface of a substrate with electromagnetic radiation having a wavelength of less than 100 nm during a deposition process, the irradiation being such as to locally drive the deposition process in the selected portion and thereby cause the deposition process to form a layer of material in a pattern defined by the selected portion, and
applying an electric field that forces electrons away from the substrate.

2. The method of claim 1, wherein the driving of the deposition process in the selected portion comprises driving a chemical reaction involving a precursor material.

3. The method of claim 2, wherein the chemical reaction comprises a photochemical reaction driven by the irradiation.

4. The method of claim 3, wherein the photochemical reaction is a multi-photon photochemical reaction involving absorption of two or more photons by each of at least one species involved in the photochemical reaction.

5. The method of claim 4, wherein the multi-photon photochemical reaction is a two-photon photochemical reaction.

6. The method of claim 2, wherein the precursor material comprises Mo(thd)₃, where thd=2,2,6,6-tetramethylheptane-3,5-dionato.

7. The method of claim 2, wherein:
the chemical reaction is at least partially driven by heat generated in the substrate by the irradiation; and
the chemical reaction comprises a pyrolytic process involving dissociation of the precursor material adsorbed to the selected portion.

8. The method of claim 2, wherein the precursor material comprises one or more selected from: BBr₃, Zn(OC₂H₅)₂, Ta(OC₂H₅)₂, Ta(OC₂H₅)₅, Al(CH₃)₃, Ti(OCH(CH₃)₂)₄.

9. The method of claim 1, wherein the deposition process comprises an atomic layer deposition process.

10. The method of claim 1, wherein the electric field is directed perpendicularly relative to the surface of the substrate.

11. The method of claim 1, wherein the electric field is applied by applying a voltage to the substrate.

12. An apparatus for forming a patterned layer of material, the apparatus comprising:
an irradiation system configured to irradiate a selected portion of a surface of a substrate with electromagnetic radiation having a wavelength of less than 100 nm during a deposition process;
an environment control system configured to allow the composition of the environment above the substrate to be controlled in such a way as to allow the deposition process to proceed; and
an electric field controller configured to apply an electric field that is oriented so as to force secondary electrons away from the substrate.

13. The apparatus of claim 12, wherein the electric field controller is configured so that the electric field is directed perpendicularly relative to the surface of the substrate.

14. The apparatus of claim 12, wherein the electric field controller is configured to apply the electric field by applying a voltage to the substrate.

15. The apparatus of claim 12, wherein the environment control system is configured to control the environment above the substrate to provide a precursor material in the environment.

16. The apparatus of claim 15, wherein:
the control of the environment is such that a portion of secondary electrons generated by interaction between the electromagnetic radiation and the substrate interact with the precursor material in the environment; and
the interaction between the secondary electrons and the precursor material is such as to promote deposition of material derived from the precursor material.

17. The apparatus of claim 12, wherein the environment control system comprises:
a chamber to provide a sealed environment including the selected portion of the surface of the substrate; and
a materials exchange system configured to allow materials to be added to and removed from the sealed environment to allow different compositional environments to be established within the sealed environment, the different compositional environments corresponding to different respective steps of the deposition process.

18. The apparatus of claim 12, wherein the irradiation system comprises a lithographic apparatus configured to provide the irradiation by projecting a patterned radiation beam from a patterning device onto the substrate.

19. A method for forming a patterned layer of material, the method comprising:
irradiating a selected portion of a surface of a substrate with electromagnetic radiation during an atomic layer deposition process, the irradiation being such as to locally drive the atomic layer deposition process in the selected portion and thereby cause the atomic layer deposition process to form a layer of material in a pattern defined by the selected portion,
wherein the atomic layer deposition process comprises two steps and the irradiation of the selected portion is performed during at least one of the two steps and while the selected portion of the substrate is in contact with a liquid.

20. The method of claim 19, further comprising processing the layer of material formed in a pattern to remove material in one or more selected regions, thereby modifying the pattern.
